(19) United States
(12) Patent Application Publication
(10) Pub. No.: US 2004/0092038 A1
(43) Pub. Date: May 13, 2004

(54) Method for forming a capacitor having a high-dielectric-constant insulation film

(75) Inventor: Naruhiko Nakanishi, Tokyo (JP)

Correspondence Address: YOUNG & THOMPSON, 745 SOUTH 23RD STREET 2ND FLOOR, ARLINGTON, VA, 22202

(73) Assignee: ELPIDA MEMORY, INC., TOKYO (JP)

(21) Appl. No.: 10/691,584

(22) Filed: Oct. 24, 2003

(30) Foreign Application Priority Data
Oct. 24, 2002 (JP) 2002-309281

(51) Int. Cl. H01L 21/8242; H01L 21/00

(52) U.S. Cl. 438/3; 438/240

(57) ABSTRACT

A method for forming a capacitor insulation film having a high dielectric constant includes the steps of depositing an amorphous strontium titanate film on a bottom electrode, forming a top electrode on the strontium titanate film and heat treating the strontium titanate film at a temperature between 500 degrees C. and 650 degrees C. in an inert gas ambient to crystallize the amorphous strontium titan ate film.

### BACKGROUND OF THE INVENTION

(a) Field of the Invention

The present invention relates to a method for forming a capacitor having a high-dielectric-constant insulation film and, more particularly, to a method for forming a strontium titanate film having a high dielectric constant in a capacitor.

(b) Description of the Related Art

In semiconductor devices such as a DRAM, there has been a strong demand for increasing a capacitance per unit area of a capacitor element in a memory cell for achieving a higher integration density. For meeting such a demand, there is a proposal for configuring the capacitor electrodes in a three-dimensional structure. However, along with development of smaller dimensions of the capacitor element, it is found that conventional dielectric films such as a silicon oxide film or silicon nitride film do not achieve a sufficient capacitance for the capacitor element merely by using the three-dimensional structure of the electrodes. Thus, insulators having higher dielectric constants, such as strontium titanate, have been studied for use as a capacitor insulation film for the capacitor element.

For employing strontium titanate as a high-dielectric-constant insulation film, a crystallized structure for strontium titanate should be provided in the filming process, which requires a higher filming temperature. However, the semiconductor integrated circuit having a capacitor element is generally susceptible to such a higher filming temperature. Patent Publication JP-A-11-274415 describes a technique for manufacturing a semiconductor device without using a high filming temperature, by depositing a strontium titanate film at a temperature below 400 degrees C. and thermally treating the strontium titanate film at temperature below 500 degrees C. for crystallization thereof to achieve a high dielectric constant for the strontium titanate.

In the technique described in the above publication, a Ti/Pt bottom electrode is formed on a barrier metal film covering a silicon substrate, followed by deposition of a strontium titanate film thereon at a temperature of 300 degrees C. The dielectric constant (relative permittivity) of the as-deposited strontium titanate film is around 100. The as-deposited strontium titanate film is then thermally treated at a temperature of 450 degrees C. in an inert gas ambient or oxidizing gas ambient to crystallize the strontium titanate film. As depicted in the accompanying drawing of the above publication the heat treatment conducted for more than five minutes provides a higher dielectric constant of around 160 for the crystallized strontium titanate. Subsequently, a top electrode of the capacitor is formed on the crystallized strontium titanate, followed by some known steps to achieve the structure for the capacitor element.

It is to be noted that a polycrystalline material such as ruthenium (Ru) is used as the material for the bottom electrode of the capacitor element in a large-capacity DRAM of 1 GHz or above. It was found in this structure, however, that the strontium titanate treated at below 500 degrees C. according to the teaching of the above publication did not effectively crystallize the strontium titanate film and thus did not provide a sufficient high dielectric constant therefor.

If the treating temperature is raised up to above 500 degrees C. in the structure, then the oxidizing gas in the oxidizing gas ambient or diffused from the strontium titanate may oxidize the underlying barrier metal film. The oxidized barrier metal film causes a problem of poor conductivity, or higher line resistance in the transistors formed thereon, which may cause reduction in the capacitance of the capacitor element.

In view of the above problems in the conventional technique, it is an object of the present invention to provide a method for manufacturing a capacitor element including a strontium titanate film having a high dielectric constant, which is capable of suppressing oxidation of the underlying barrier metal film.

The present invention provides a method for forming a capacitor element having a capacitor insulation film made of strontium titanate, including the steps of: depositing a strontium titanate film; and heat treating the strontium titanate film at a temperature between 500 degrees C. and 650 degrees C. in an inert gas ambient.

The present invention also provides a method for forming a capacitor element in an LSI, including the steps of: forming a bottom electrode overlying a semiconductor substrate; depositing a strontium titanate film on the bottom electrode; forming a top electrode on the strontium titanate film; and heat treating the strontium titanate film at a temperature between 500 degrees C. and 650 degrees C. in an inert gas ambient.

In accordance with the method of the present invention, the heat treatment between 500 degrees C. and 650 degrees C. effectively crystallizes the as-deposited strontium titanate film, thereby allowing the same to have a higher dielectric constant. In addition, the heat treatment suppresses oxidation of the barrier metal film underlying the bottom electrode of the capacitor element.

The above and other objects, features and advantages of the present invention will be more apparent from the following description, referring to the accompanying drawings.

### BRIEF DESCRIPTION OF THE DRAWINGS

FIGS. 1A to 1C are sectional views of a semiconductor device during consecutive steps of forming a capacitor.

FIG. 2 is a graph showing the temperature dependency of the dielectric constant of strontium titanate films obtained by heat treatments.

FIG. 3 is a graph showing the temperature dependency of the equivalent thickness of the strontium titanate films in terms of the thickness of SiO₂ film.

### PREFERRED EMBODIMENTS OF THE INVENTION

Now, the present invention is more specifically described with reference to accompanying drawings.

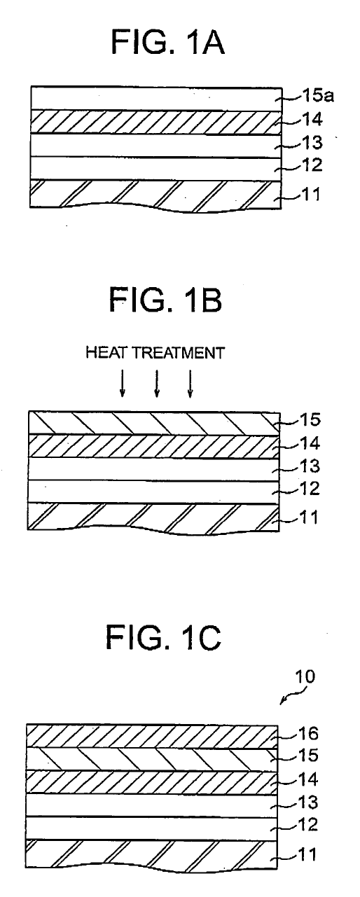

Referring to FIGS. 1A to 1C, there is shown a process for forming a capacitor element having a strontium titanate film according to a first embodiment of the present invention.

A semiconductor substrate (silicon substrate) 11 is prepared, on which a polycrystalline silicon (polysilicon) film 12, a titanium nitride (TiN) barrier metal film 13, polycrystalline ruthenium bottom electrode 14 are consecutively formed. Subsequently, an amorphous strontium titanate film 15a is deposited on the bottom electrode 14, as shown in FIG. 1A.

Thereafter, as shown in FIG. 1B, a heat treatment is conducted at a temperature between 500 degrees C. and 650 degrees C. in an inert gas ambient for crystallizing the amorphous strontium titanate film 15a to obtain a single-crystal strontium titanate film 15. This crystallization process allows the single-crystal strontium titanate 15 to assume an insulating film having a higher dielectric constant. Examples of the inert gas include halogen gases such as argon (Ar) and helium (He), as well as nitrogen (N₂) which does not react with substances in the capacitor element. Subsequently, a top electrode 16 is formed on the strontium titanate film 15, followed by some known steps to thereby achieve the capacitor element 10.

In the above embodiment, the amorphous strontium titanate film 15a deposited on the polycrystalline ruthenium bottom electrode 14 is crystallized by the heat treatment at 500 degrees C. or above to form a single-crystal strontium titanate film 15 having a higher dielectric constant. The heat treatment conducted in the inert gas ambient suppresses oxidation of the barrier metal film 13 because oxidizing gas is not provided to the barrier metal film 13 from the inert gas ambient. In addition, the heat treatment at 650 degrees C. or below also suppresses the oxidation of barrier metal film caused by diffusion of oxygen from the strontium titanate film 15.

Referring again to FIGS. 1A to 1C, a process according to a second embodiment of the present invention will be described hereinafter. The steps up to the step of depositing the ruthenium bottom electrode 14 in the present embodiment are similar to those in the first embodiment. After forming the bottom electrode 14, an amorphous strontium titanate film 15a having a thickness of about 20 nm is deposited on the bottom electrode 14 at a temperature of 420 degrees C. by using a CVD process, as shown in FIG. 1A.

Thereafter, as shown in FIG. 1B, a heat treatment is conducted at a temperature between 500 degrees C. and 650 degrees C. in a nitrogen (N₂) gas ambient by using a rapid thermal annealing (RTA) process for one minute, thereby crystallizing the amorphous strontium titanate film 15a to form a single-crystal strontium titanate film 15. The crystallization process allows the strontium titanate film 15 to have a higher dielectric constant. Thereafter, as shown in FIG. 1C, a top electrode 16 is formed on the single-crystal strontium titanate film 15, followed by some known steps to achieve the capacitor element in the semiconductor device. The heat treatment using a RTA technique may be conducted for a time interval between 15 seconds and five 15 minutes.

In the second embodiment, the heat treatment conducted at a temperature between 500 degrees C. and 650 degrees C. allows the amorphous strontium titanate film to assume a single-crystal strontium titanate film having a higher dielectric constant while suppressing oxidation of the barrier metal film, which may be caused by oxygen gas generated by diffusion of oxygen from the strontium titanate film 15. Oxidation of the barrier metal film caused by oxygen gas from the oxidizing ambient can be also suppressed by the heat treatment using the inert gas ambient. The RTA process conducted for a short time interval of about one minute reduces the influence on the films by the heat treatment.

The heat treatment in the above embodiments may be conducted after forming the top electrode 16 instead of conducting directly after depositing the strontium titanate film.

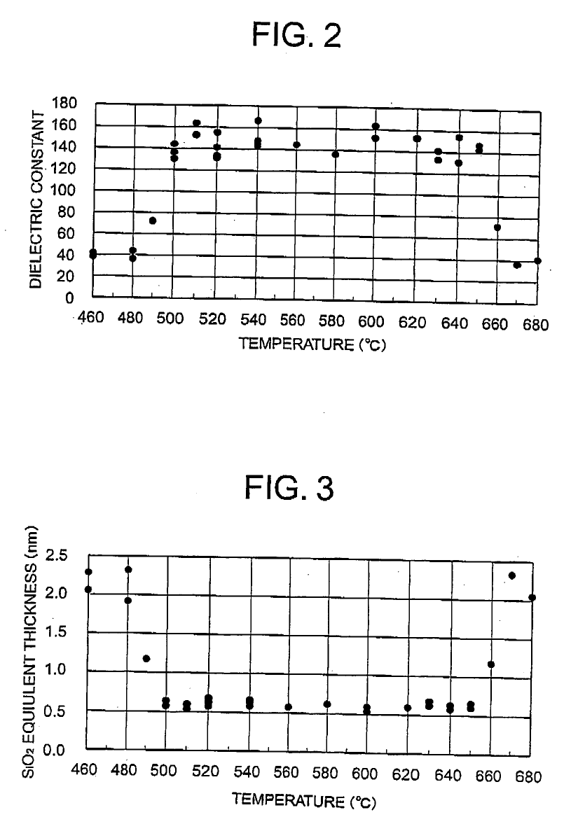

Referring to FIG. 2, there is shown the relationship between the temperature of the heat treatment and the dielectric constant of the strontium titanate film obtained by the heat treatment. As understood from FIG. 2, a heat treatment between 500 degrees C. and 650 degrees C. allows crystallization of the amorphous strontium titanate to proceed, thereby raising the dielectric constant up to between 130 and 170, On the other hand, a heat treatment at a temperature above 650 degrees C. may enhance oxidation of the barrier metal film, TiN film, 13 to thereby lower the capacitance of the capacitor element. Thus, the apparent dielectric constant of the capacitor insulation film is reduced by the heat treatment at above 650 degrees C.

FIG. 3 shows the equivalent thickness of the strontium titanate film obtained by the process of the above embodiments, the equivalent thickness being expressed in terms of the thickness of SiO₂ to show the degree of dielectric constant of the strontium titanate film. As understood from FIG. 3, the equivalent thickness of the strontium titanate film obtained by the above embodiments assumes a lower value of 1 nm or below at the temperatures between 500 degrees C. and 650 degrees C. of the heat treatment, thereby showing a higher dielectric constant of the strontium titanate film obtained by the method of the present invention.

Since the above embodiments are described only for examples, the present invention is not limited to the above embodiments and various modifications or alterations can be easily made therefrom by those skilled in the art without departing from the scope of the present invention.

What is claim is:

1. A method for forming a capacitor element having a capacitor insulation film made of strontium titanate, comprising the steps of:
depositing a strontium titanate film; and
heat treating said strontium titanate film at a temperature between 500 degrees C. and 650 degrees C. in an inert gas ambient.

2. The method according to claim 1, wherein said heat treating step crystallizes as-deposited said strontium titanate film which is an amorphous film.

3. The method according to claim 1, wherein said inert gas includes at least one of argon, helium and nitrogen as a main component thereof.

4. The method according to claim 1, wherein said heat treating step includes rapid thermal annealing conducted for a time interval between 15 seconds and five minutes.

5. A method for forming a capacitor element in an LSI, comprising the steps of:
forming a bottom electrode overlying a semiconductor substrate;
depositing a strontium titanate film on said bottom electrode;
forming a top electrode on said strontium titanate film; and
heat treating said strontium titanate film at a temperature between 500 degrees C. and 650 degrees C. in an inert gas ambient.

6. The method according to claim 5, wherein said bottom electrode includes a plurality of layers including a silicon layer and/or titanium nitride layer.

7. The method according to claim 5, wherein said heat treating step crystallizes as-deposited said strontium titanate film which is an amorphous film.

8. The method according to claim 5, wherein said inert gas includes at least one of argon, helium and nitrogen as a main component thereof.

9. The method according to claim 5, wherein said heat treating step includes rapid thermal annealing conducted for a time interval between 15 seconds and five minutes
